(19) United States
(12) Patent Application Publication
(10) Pub. No.: US 2016/0112024 A1
(43) Pub. Date: Apr. 21, 2016

(54) INDUCTOR CIRCUIT INTEGRATED WITH RC CIRCUIT

(71) Applicant: HON HAI PRECISION INDUSTRY CO., LTD., New Taipei (TW)

(72) Inventors: CHI-KUNG SU, New Taipei (TW); JYUN-DA LIAO, New Taipei (TW); WEI-LUNG HUANG, New Taipei (TW)

(21) Appl. No.: 14/516,514

(22) Filed: Oct. 16, 2014

(51) Int. Cl. H03H 1/02; H01F 27/29

(52) U.S. Cl. CPC H03H 1/02; H01F 27/29

(57) ABSTRACT

An inductor circuit includes an inductor and an RC circuit. The RC circuit includes a resistor and a capacitor. The resistor and the capacitor are coupled in series. A first terminal of the inductor is coupled to the resistor through a first contact. The resistor is coupled to the capacitor through a second contact. The capacitor is coupled to a second terminal of the inductor through a third contact.

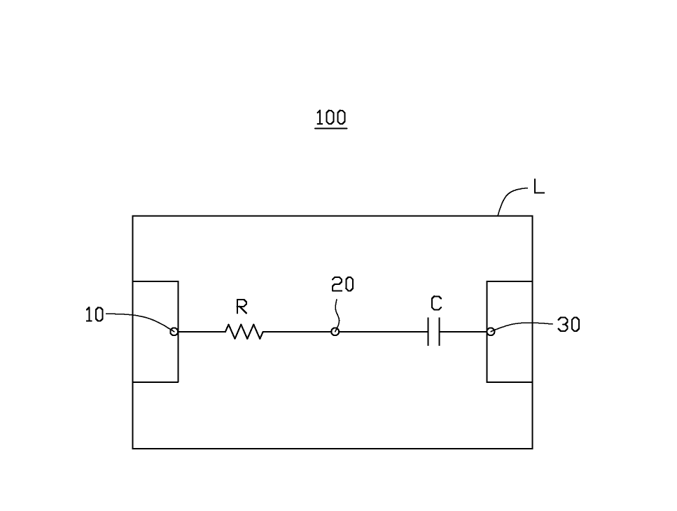

### FIELD

The present disclosure relates to an inductor circuit integrated with an RC circuit.

### BACKGROUND

Wire resistance plays an important role in electrical experiment and design.

### BRIEF DESCRIPTION OF THE DRAWING

Implementations of the present technology will now be described, by way of example only, with reference to the attached FIGURE.

The FIGURE is a circuit diagram of an embodiment of an inductor circuit integrated with an RC circuit.

### DETAILED DESCRIPTION

Numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series and the like. The FIGURE shows an embodiment of an inductor circuit integrated with an RC circuit.

The inductor circuit 100 can comprise an inductor L, a resistor R, and a capacitor C. The resistor R and the capacitor C are coupled in series forming an RC circuit. A first terminal of the inductor L is coupled to a second terminal of the inductor L through the resistor R and the capacitor C, in that order. The first terminal of the inductor L is coupled to the resistor R through a first contact 10. The resistor R is coupled to the capacitor C through a second contact 20. The capacitor C is coupled to the second terminal of the inductor L through a third contact 30. The first contact 10, the second contact 20, and the third contact 30 are on the surface layer of the inductor circuit 100. A resistance R1 of the resistor R, a capacitance C1 of the capacitor C, an inductance L1 of the inductor L, and a resistance R2 of the inductor L satisfy a first equation L1/R2=C1*R1.

The inductor L and the RC circuit are coupled in parallel. A second equation (sL1+R2)Is−LI(0_)=R1[sC1V(c)−CV(0_)]+V(c) is based on complex frequency domain. The Is in the second equation stands for an instant current in the inductor L. The I(0_) in the second equation stands for an initial current in the inductor L. The V(0_) in the second equation stands for an initial voltage across the capacitor C. The V(c) in the second equation stands for an instant voltage across the capacitor C. A third equation can be derived from the second equation. The third equation can be: V(c)=Is(sL1+R2)/(sC1R1+1)+[C1R1V(0_)−L1I(0_)]/(sC1R1+1). A second part of the third equation “[C1R1V(0_)−L1I(0_)]/(sC1R1+1)” is decreased to zero according to the index law. So a fourth equation 4 can be derived from the third equation. The fourth equation can be: V(c)=Is(sL1+R2)/(sC1R1+1). Thus, a fifth equation “V(c)=R2*Is” when L1/R2=C1*R1 results.

In use, probes can be used to contact the second contact 20 and the third contact 30 to establish the voltage V(c) across the capacitor C. Then the current Is in the inductor L can be established based on the fifth equation.

The embodiment shown and described above is only an example. Many details are often found in the art. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the following claims.

What is claimed is:

1. An inductor circuit comprising:
an inductor;
a resistor and a capacitor coupled in series forming an RC circuit, wherein a resistance R1 of the resistor and a capacitance C1 of the capacitor satisfy the equation L1/R2=C1*R1; the RC circuit and the inductor are coupled in parallel, a first terminal of the inductor is coupled to the resistor through a first contact,
wherein the resistor is coupled to the capacitor through a second contact, and the capacitor is coupled to a second terminal of the inductor through a third contact.

2. The inductor circuit of claim 1, wherein the first contact, the second contact, and the third contact are on a surface layer of the inductor circuit.
